(19) United States
(12) Patent Application Publication
(10) Pub. No.: US 2026/0214796 A1
(43) Pub. Date: Jul. 23, 2026

(54) ELECTRONIC DEVICE

(71) Applicant: AUO Corporation, Hsinchu City (TW)

(72) Inventors: Yi-Ta Chen, Hsinchu City (TW); Kuan-Yi Lee, Hsinchu City (TW); Shih-Ming Chen, Hsinchu City (TW)

(73) Assignee: AUO Corporation, Hsinchu City (TW)

(21) Appl. No.: 19/235,588

(22) Filed: Jun. 12, 2025

(30) Foreign Application Priority Data
Jan. 20, 2025 (TW) 114102248

(51) Int. Cl. H05K 1/11; H05K 1/18; H05K 3/28

(52) U.S. Cl. CPC H05K 1/111; H05K 1/181; H05K 3/285; H05K 2201/0112; H05K 2203/107

(57) ABSTRACT

An electronic device including a circuit substrate and a first filling layer is provided. The circuit substrate includes a base and a first pad and a second pad disposed on the base. The first filling layer includes a first portion located between the first pad and the second pad. The first pad and the second pad are suitable for respectively connecting two electrodes of a first electronic component. The first filling layer has an absorption rate greater than 80% for light in a range of 200 nm to 355 nm.

### CROSS-REFERENCE TO RELATED APPLICATION

This application claims the priority benefit of Taiwan application serial no. 114102248, filed on Jan. 20, 2025. The entirety of the above-mentioned patent application is hereby incorporated by reference herein and made a part of this specification.

### BACKGROUND

### Technical Field

The disclosure relates to an electronic device.

### Description of Related Art

Electronic devices usually include a large number of electronic components, and laser light may be used to form the bonding between the electronic components and a base. However, during the scanning process of the laser light, the non-bonding area may also be heated by the laser light, resulting in damage to the components within the area or causing a short circuit in the electronic device.

### SUMMARY

An electronic device, in which the non-bonding area is protected and the yield is high, is provided in the disclosure.

According to an embodiment of the disclosure, an electronic device including a circuit substrate and a first filling layer is provided. The circuit substrate includes a base and a first pad and a second pad disposed on the base. The first filling layer includes a first portion located between the first pad and the second pad. The first pad and the second pad are suitable for respectively connecting two electrodes of a first electronic component. The first filling layer has an absorption rate greater than 80% for light in a range of 200 nm to 355 nm.

According to another embodiment of the disclosure, an electronic device including a circuit substrate and a first filling layer is provided. The circuit substrate includes a base and a first pad, a second pad, a third pad and a fourth pad disposed on the base. The first filling layer includes a first portion located between the first pad and the second pad and a second portion located between the third pad and the fourth pad. The first pad and the second pad are suitable for respectively connecting two electrodes of a first electronic component, and the third pad and the fourth pad are suitable for respectively connecting two electrodes of a second electronic component. The second portion of the first filling layer includes a top surface defining a first virtual reference plane, and the first portion of the first filling layer includes at least one concave surface located between the first virtual reference plane and the base.

Based on the above, the electronic device provided by the embodiment of the disclosure utilizes the first filling layer to absorb the laser light configured to destroy the bonding between the pad and the electrode, thereby preventing the laser light from damaging the components in the base.

In order to make the above-mentioned features and advantages of the disclosure comprehensible, embodiments accompanied with drawings are described in detail below.

### BRIEF DESCRIPTION OF THE DRAWINGS

FIG. 1A shows a schematic diagram of an electronic device according to a first embodiment of the disclosure in a first state, FIG. 1B shows a schematic diagram of an electronic device according to the first embodiment of the disclosure in a second state, and FIG. 1C shows a schematic diagram of an electronic device according to the first embodiment of the disclosure in a third state.

FIG. 2A shows a schematic diagram of an electronic device according to a second embodiment of the disclosure in a first state, FIG. 2B shows a schematic diagram of an electronic device according to the second embodiment of the disclosure in a second state, and FIG. 2C shows a schematic diagram of an electronic device according to the second embodiment of the disclosure in a third state.

FIG. 3 shows a schematic diagram of an electronic device according to some embodiments of the disclosure.

FIG. 4 shows a schematic diagram of an electronic device according to some embodiments of the disclosure.

### DETAILED DESCRIPTION OF DISCLOSED EMBODIMENTS

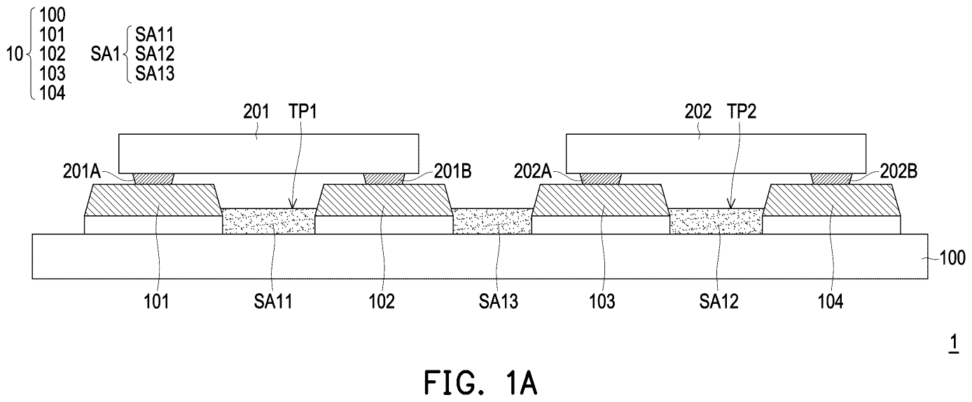

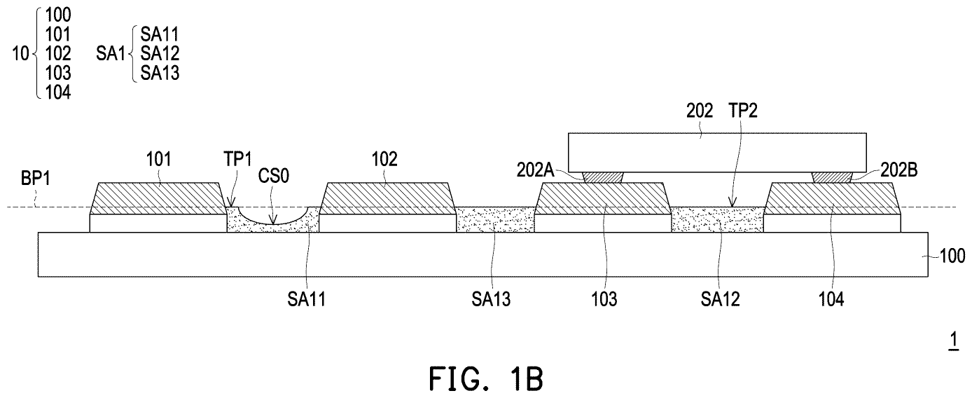

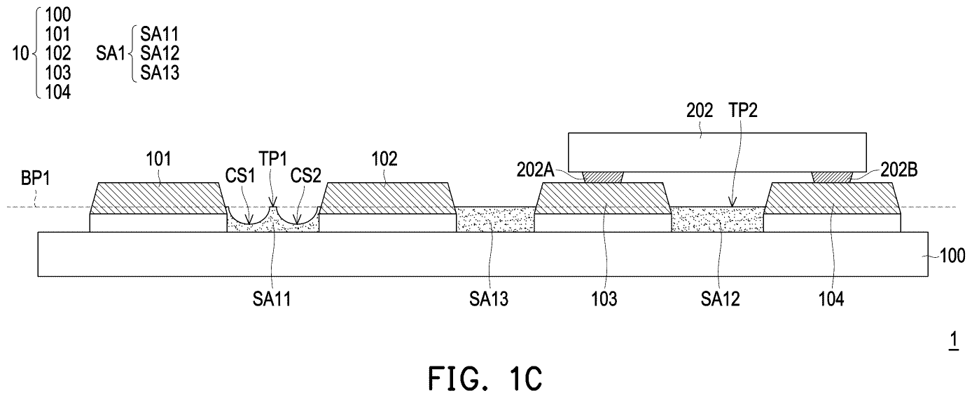

Referring to FIG. 1A, FIG. 1B and FIG. 1C, FIG. 1A shows a schematic diagram of an electronic device according to a first embodiment of the disclosure in a first state, FIG. 1B shows a schematic diagram of an electronic device according to the first embodiment of the disclosure in a second state, and FIG. 1C shows a schematic diagram of an electronic device according to the first embodiment of the disclosure in a third state.

The electronic device 1 of the first embodiment includes a circuit substrate 10, a filling layer SA1, an electronic component 201, and an electronic component 202. The circuit substrate 10 includes a base 100, a pad 101, a pad 102, a pad 103 and a pad 104, in which the pads 101 and 102 are arranged in pairs, and the pads 103 and 104 are arranged in pairs. The filling layer SA1 includes a first portion SA11 located between the pad 101 and the pad 102 and a second portion SA12 located between the pad 103 and the pad 104. The first portion SA11 and the second portion SA12 include the same material, and a top surface TP1 of the first portion SA11 is substantially coplanar with a top surface TP2 of the second portion SA12. The electronic component 201 includes an electrode 201A and an electrode 201B. The electronic component 202 includes an electrode 202A and an electrode 202B. The pad 101 is connected to the electrode 201A, the pad 102 is connected to the electrode 201B, the pad 103 is connected to the electrode 202A, and the pad 104 is connected to the electrode 202B.

The filling layer SA1 may include, for example, a (meth)acrylate copolymer and analogous materials thereof. In a preferred embodiment, the filling layer SA1 may have an absorption rate greater than 80% for light in the range of 200 nm to 355 nm. In a more preferred embodiment, the filling layer SA1 may have an absorption rate greater than 95% for light in the range of 200 nm to 355 nm.

When the electronic component 201 of the electronic device 1 is damaged, light (e.g., laser light) in the range of 200 nm to 355 nm is required to destroy the bonding between the pad 101 and the electrode 201A and the bonding between the pad 102 and the electrode 201B to remove the damaged electronic component 201. In a comparative example, the electronic device 1 is not provided with the filling layer SA1, and when the laser light irradiates the surface of the base 100 between the pad 101 and the pad 102, the components of the base 100 near the surface may be damaged.

In contrast, in the first embodiment, a filling layer SA1 (i.e., a first portion SA11 of the filling layer SA1) is disposed on the surface of the base 100 between the pad 101 and the pad 102, and the filling layer SA1 may have an absorption rate greater than 80% for laser light in the range of 200 nm to 355 nm. Therefore, the first portion SA11 of the filling layer SA1 may absorb the laser light configured to remove the electronic component 201, thereby preventing excessive exposure of the surface of the base 100 between the pad 101 and the pad 102 to the laser light, which could lead to damage of the components in the base 100.

In some embodiments, the first portion SA11 of the filling layer SA1 may generate gas including carbon dioxide and carbon monoxide, and gas including water molecules after being irradiated by laser light in the range of 200 nm to 355 nm, but the disclosure is not limited thereto.

In some embodiments, the first portion SA11 of the filling layer SA1 may form a concave surface CS0 after being irradiated by the laser light, as shown in FIG. 1B. The concave surface CS0 is located between a virtual reference plane BP1 and the base 100, and the virtual reference plane BP1 is coplanar with a top surface TP2 of the second portion SA12, in which the second portion SA12 is not irradiated by the laser light. In other words, the first portion SA11 irradiated by the laser light forms a concave surface CS0 that is recessed relative to the top surface TP1 thereof.

However, the disclosure is not limited to the structure shown in FIG. 1B. In some embodiments, the first portion SA11 irradiated by the laser light may form multiple concave surfaces (e.g., the concave surface CS1 and the concave surface CS2 shown in FIG. 1C) that are recessed relative to the top surface TP1. The concave surfaces CS1 and CS2 are located between the virtual reference plane BP1 and the base 100.

It should be further explained that, although in the structures shown in FIG. 1B and FIG. 1C, the surface of the base 100 between the pad 101 and the pad 102 is completely covered by the filling layer SA1, the disclosure is not limited thereto. In some embodiments, at least a portion of the surface of the base 100 between the pad 101 and the pad 102 may be exposed by the filling layer SA1.

In some embodiments, the filling layer SA1 has an absorption rate of less than 5% for light in the range of 900 nm to 1000 nm that may be configured to bond the electronic components 201 and 202 and the circuit substrate 10. Accordingly, the filling layer SA1 may be prevented from deterioration during the process of bonding the electronic components 201 and 202 and the circuit substrate 10.

In some embodiments, the filling layer SA1 may also absorb the gas generated by destroying the bonding between the pad 101 and the electrode 201A, thereby reducing the amount of solder residue and the residue of the electronic component 201.

In the structure shown in FIG. 1A to FIG. 1C, the filling layer SA1 may further include a third portion SA13, in which the first portion SA11, the second portion SA12, and the third portion SA13 include the same material. The first portion SA11 and the second portion SA12 are both disposed between paired pads, and the third portion SA13 is not disposed between paired pads. However, the electronic device provided by the disclosure is not limited to the above structure. In some embodiments, the filling layer SA1 may be disposed only between paired pads.

In order to fully illustrate the various embodiments of the disclosure, other embodiments of the disclosure are described below. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

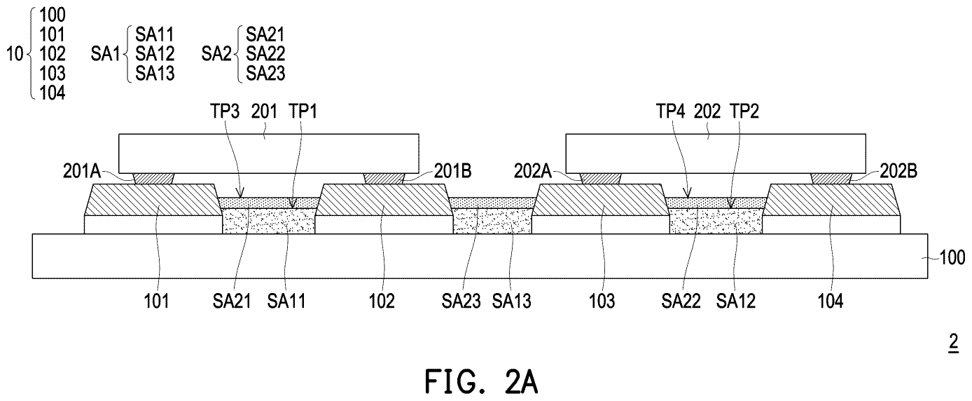

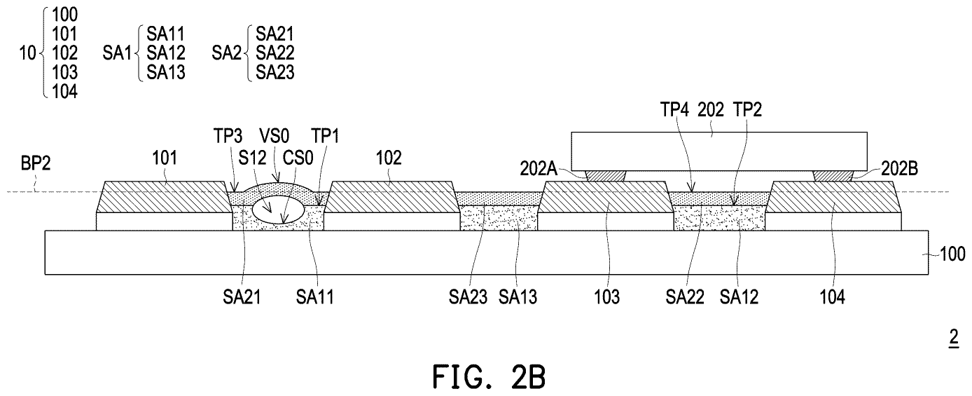

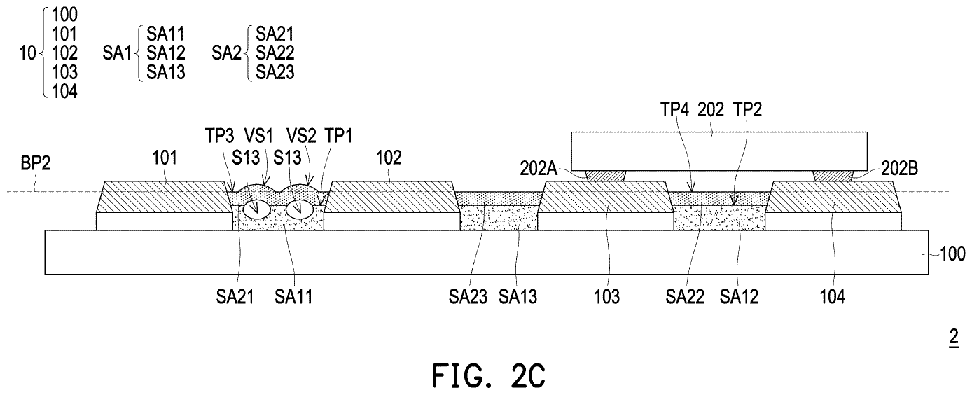

Referring to FIG. 2A, FIG. 2B and FIG. 2C, FIG. 2A shows a schematic diagram of an electronic device according to a second embodiment of the disclosure in a first state, FIG. 2B shows a schematic diagram of an electronic device according to the second embodiment of the disclosure in a second state, and FIG. 2C shows a schematic diagram of an electronic device according to the second embodiment of the disclosure in a third state.

Compared with the aforementioned electronic device 1, the electronic device 2 of the second embodiment further includes a filling layer SA2 disposed on the filling layer SA1. The filling layer SA2 includes a first portion SA21 located between the pad 101 and the pad 102 and a second portion SA22 located between the pad 103 and the pad 104. The first portion SA21 and the second portion SA22 include the same material, and a top surface TP3 of the first portion SA21 is substantially coplanar with a top surface TP4 of the second portion SA22.

The filling layer SA2 may include, for example, a tackifier resin, in which the tackifier resin may include a phenolic hydroxyl group, a hydroxymethyl group, a carboxyl group, an ester bond, an ether bond, and analogous materials thereof. In some embodiments, the filling layer SA2 has an absorption rate of less than 20% for light in the range of 200 nm to 355 nm. Accordingly, when laser light in the range of 200 nm to 355 nm is required to destroy the bonding between the pad 101 and the electrode 201A and the bonding between the pad 102 and the electrode 201B, the laser light may penetrate the first portion SA21 of the filling layer SA2 and be absorbed by the first portion SA11 of the filling layer SA1. Accordingly, as described in the first embodiment, the first portion SA11 of the filling layer SA1 may protect the components in the base 100, and the first portion SA21 of the filling layer SA2 may block the gas generated by the first portion SA11 irradiated by the laser light, thereby preventing the gas from contaminating the electronic device 2.

Specifically, referring to FIG. 2A and FIG. 2B, when laser light in the range of 200 nm to 355 nm is required to destroy the bonding between the pad 101 and the electrode 201A and the bonding between the pad 102 and the electrode 201B, the laser light may penetrate the first portion SA21 of the filling layer SA2 and be absorbed by the first portion SA11 of the filling layer SA1. After being irradiated by the laser light, the first portion SA11 of the filling layer SA1 may form a concave surface CS0 (as shown in FIG. 2B) and generate gas. The filling layer SA2 with high viscosity may bulge upward to form a cavity S12 surrounded by the first portion SA11 of the filling layer SA1 and the first portion SA21 of the filling layer SA2. The gas generated by the first portion SA11 of the filling layer SA1 may be confined within the cavity S12 and thus does not contaminate the electronic device 2. As shown in FIG. 2B, the first portion SA21 with high viscosity is subjected to pressure from the gas in the cavity S12 to form a convex surface VS0. A virtual reference plane BP2 is located between the convex surface VS0 and the base 100, and the virtual reference plane BP2 is coplanar with the top surface TP4 of the second portion SA22, in which the second portion SA22 of the filling layer SA2 is not irradiated by the laser light.

However, the disclosure is not limited to the structure shown in FIG. 2B. In some embodiments, the first portion SA21 irradiated by the laser light may form multiple convex surfaces (e.g., the convex surface VS1 and the convex surface VS2 shown in FIG. 2C) protruding relative to the top surface TP3 and multiple cavities S13. The virtual reference plane BP2 is located between the convex surfaces VS1 and VS2 and the base 100.

In the structure shown in FIG. 2A to FIG. 2C, the filling layer SA2 may further include a third portion SA23, in which the first portion SA21, the second portion SA22, and the third portion SA23 include the same material. The first portion SA21 and the second portion SA22 are both disposed between the paired pads, and the third portion SA23 is not disposed between paired pads. However, the electronic device provided by the disclosure is not limited to the above structure. In some embodiments, the filling layer SA2 may be disposed only between paired pads.

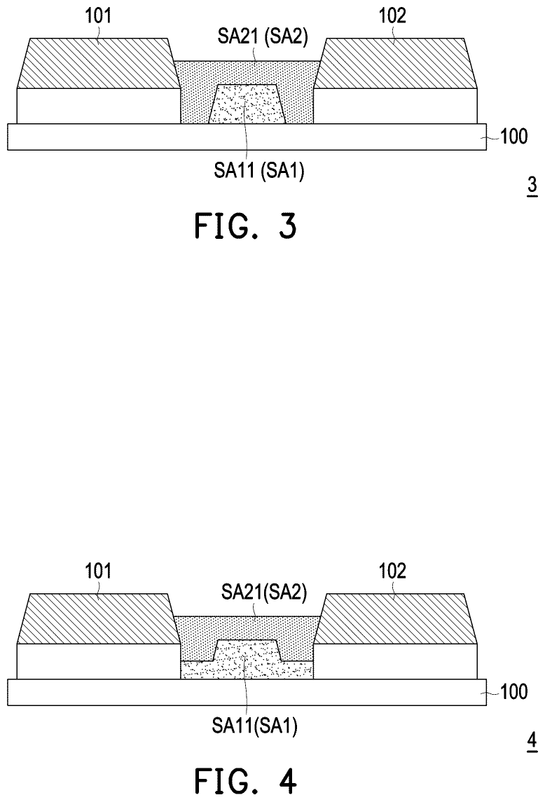

Furthermore, the disclosure is not limited to the electronic device 2 shown in FIG. 2A. In some embodiments, the first portion SA11 and the first portion SA21 between the pad 101 and the pad 102 and the second portion SA12 and the second portion SA22 between the pad 103 and the pad 104 may be configured as shown in FIG. 3 and FIG. 4 to be described below. Furthermore, for ease of understanding, the structures shown in FIG. 3 and FIG. 4 are described using only the first portion SA11 and the first portion SA21 between the pad 101 and the pad 102.

Referring to FIG. 3, FIG. 3 shows a schematic diagram of an electronic device according to some embodiments of the disclosure. The electronic device 3 of this embodiment has substantially the same structure as the electronic device 2 of the second embodiment, and the main difference is that a partial surface of the base 100 between the pad 101 and the pad 102 of the electronic device 3 is exposed by the first portion SA11 of the filling layer SA1. Accordingly, when laser light in the range of 200 nm to 355 nm is required to destroy the bonding between the pads 101 and 102 and the corresponding electrodes, the position of the upwardly protruding portion of the first portion SA21 of the filling layer SA2 may be determined by the position of the first portion SA11 of the filling layer SA1. For the structure shown in FIG. 3, the upwardly protruding portion of the first portion SA21 of the filling layer SA2 is located at the center of the region between the pad 101 and the pad 102.

Referring to FIG. 4, FIG. 4 shows a schematic diagram of an electronic device according to some embodiments of the disclosure. The electronic device 4 of this embodiment has substantially the same structure as the electronic device 2 of the second embodiment, and the main difference is that the first portion SA11 of the filling layer SA1 of the electronic device 4 has a first thickness T1 in its central portion and a second thickness T2 in its peripheral portion, and the first thickness T1 is greater than the second thickness T2. Accordingly, when laser light in the range of 200 nm to 355 nm is required to destroy the bonding between the pads 101 and 102 and the corresponding electrodes, the position of the upwardly protruding portion of the first portion SA21 of the filling layer SA2 may be located at the center of the region between the pad 101 and the pad 102.

To sum up, the electronic device provided by the embodiment of the disclosure utilizes the filling layer (the first filling layer) to absorb the laser light configured to destroy the bonding between the pad and the electrode, thereby preventing the laser light from damaging the components in the base. The electronic device also uses another filling layer (the second filling layer) to limit the gas generated by the first filling layer, thereby preventing the electronic device from being contaminated by the gas.

What is claimed is:

1. An electronic device, comprising:
a circuit substrate, comprising a base and a first pad and a second pad disposed on the base; and
a first filling layer, comprising a first portion located between the first pad and the second pad,
wherein the first pad and the second pad are suitable for respectively connecting two electrodes of a first electronic component, and
wherein the first filling layer has an absorption rate greater than 80% for light in a range of 200 nm to 355 nm.

2. The electronic device according to claim 1, wherein the first filling layer has an absorption rate greater than 95% for the light in the range of 200 nm to 355 nm.

3. The electronic device according to claim 1, wherein the first filling layer has an absorption rate of less than 5% for the light in a range of 900 nm to 1000 nm.

4. The electronic device according to claim 1, wherein the first filling layer comprises a (meth)acrylate copolymer.

5. The electronic device according to claim 1, wherein the first filling layer generates a gas, and the gas comprises at least one of carbon dioxide, carbon monoxide and water molecules when the first filling layer is irradiated by light in the range of 200 nm to 355 nm.

6. The electronic device according to claim 1, further comprising a second filling layer, disposed on the first filling layer, wherein the second filling layer has an absorption rate of less than 20% for light in the range of 200 nm to 355 nm.

7. The electronic device according to claim 6, wherein a partial surface of the base between the first pad and the second pad is exposed by the first portion of the first filling layer.

8. The electronic device according to claim 6, wherein the first portion of the first filling layer has a first thickness and a second thickness, and the first thickness is different from the second thickness.

9. The electronic device according to claim 6, wherein the second filling layer comprises a tackifier resin.

10. An electronic device, comprising:
a circuit substrate, comprising a base and a first pad, a second pad, a third pad and a fourth pad disposed on the base; and
a first filling layer, comprising a first portion located between the first pad and the second pad and a second portion located between the third pad and the fourth pad,
wherein the first pad and the second pad are suitable for respectively connecting two electrodes of a first electronic component, and the third pad and the fourth pad are suitable for respectively connecting two electrodes of a second electronic component, and
wherein the second portion of the first filling layer comprises a top surface defining a first virtual reference plane, and the first portion of the first filling layer comprises at least one concave surface located between the first virtual reference plane and the base.

11. The electronic device according to claim 10, wherein the first filling layer comprises a (meth)acrylate copolymer.

12. The electronic device according to claim 10, further comprising a second filling layer, disposed on the first filling layer, and comprising a first portion located between the first pad and the second pad and a second portion located between the third pad and the fourth pad, wherein the second portion of the second filling layer comprises a top surface defining a second virtual reference plane, the first portion of the second filling layer comprises at least one convex surface, and the second virtual reference plane is located between the base and the at least one convex surface.

13. The electronic device according to claim 12, wherein at least one cavity is provided between the first portion of the second filling layer and the first portion of the first filling layer.

14. The electronic device according to claim 12, wherein the second filling layer comprises a tackifier resin.

15. The electronic device according to claim 10, wherein the first filling layer has an absorption rate greater than 80% for light in a range of 200 nm to 355 nm.
